(19) United States
(12) Patent Application Publication
(10) Pub. No.: US 2025/0371224 A1
(43) Pub. Date: Dec. 4, 2025

(54) METHOD TO OPTIMIZE RATE RAMP DOWN IN A WELLBORE

(71) Applicant: Halliburton Energy Services, Inc., Houston, TX (US)

(72) Inventors: Zhijie Sun, Houston, TX (US); Derek Shelby Bale, Houston, TX (US); Dinesh Ananda Shetty, Houston, TX (US); Elijah Sterling Bogle, Houston, TX (US); Sergei Parsegov, Houston, TX (US)

(21) Appl. No.: 19/013,554

(22) Filed: Jan. 8, 2025

Related U.S. Application Data
(60) Provisional application No. 63/653,249, filed on May 30, 2024.
(60) Provisional application No. 63/654,764, filed on May 31, 2024.

(51) Int. Cl. G06F 30/27; G06F 30/28

(52) U.S. Cl. CPC G06F 30/27; G06F 30/28

(57) ABSTRACT

A method, apparatus, and non-transitory, computer readable medium are disclosed herein for optimizing a pressure pulse signal during ramp down operations for a hydraulic fracturing process in a wellbore. In one embodiment, a method comprises: obtaining pressure pulse data from a wellbore; calculating wave speed for the wellbore; and determining a rate change schedule for use during a ramp down procedure based on the wave speed.

### CLAIM OF PRIORITY

This application claims priority to U.S. Provisional Application No. 63/653,249, filed May 30, 2024, entitled “METHOD TO OPTIMIZE RATE RAMP DOWN IN A WELLBORE,” the entire content of which is incorporated herein by reference.

### FIELD

Some implementations relate generally to the field of downhole fluid flow and more particularly to the field of determining a rate change schedule for optimizing a pressure pulse signal during ramp down operations for a hydraulic fracturing process in a wellbore.

### BACKGROUND

In the oil and gas industry, hydraulic fracturing is a common method used to create high conductive pathways inside the reservoirs and thus productivity of such reservoirs. In hydrocarbon recovery operations, one or more fluids and proppants may be introduced into the well. During each hydraulic fracturing treatment, a rate ramp down stage may occur during operations or at a desired end of operations, wherein the pumping pressure is decreased from a steady-state pumping pressure. Pressure pulse signals obtained from the rate decrease during a ramp down procedure may provide valuable information about the wellbore condition and/or neighboring formations and offset wellbores. As such, a specially tailored schedule of the pumping rate changes may be needed to provide an optimum pressure signal.

### BRIEF DESCRIPTION OF THE DRAWINGS

Implementation of the disclosure may be better understood by referencing the accompanying drawings.

FIG. 1 is a diagrammatic illustration of an example well system, according to some implementations.

FIGS. 2A and 2B are graphical representations that illustrate pressure signals obtained during rate chance procedures, such as ramp down procedures, according to some implementations.

FIG. 3 is a graphical representation illustrating a pressure signal obtained using one approach for calculating a rate change schedule for a ramp down procedure, according to some implementations.

FIGS. 4A and 4B are graphical representations illustrating pressure signals obtained using alternate approaches for calculating a rate change schedule for a ramp down procedure, according to some implementations.

FIG. 5 is a flowchart depicting example operations to determine a rate change schedule, according to some implementations.

FIG. 6 is an example neural network that may be implanted with a learning machine, according to some implementations.

FIG. 7 is a block diagram depicting an example computer, according to some implementations.

### DESCRIPTION

The description that follows includes example systems, methods, techniques, and program flows that embody aspects of the disclosure. However, it is understood that this disclosure may be practiced without these specific details. For instance, this disclosure refers to collecting geometrical data and fluid properties, which may include pressure pulse data, and determining a rate change schedule to obtain an ideal pressure pulse signal for a wellbore. In some implementations, a learning machine may be trained and used to determine the rate change schedule. Aspects of this disclosure can also be applied to any other configuration of a device to obtain inputs for any suitable learning machine to determine properties of the fluid. For clarity, some well-known instruction instances, protocols, structures, and techniques have been omitted.

Example implementations relate to obtaining data from fluids and pressure pulses in a wellbore and generating an optimal pressure pulse during a ramp down part of a hydraulic fracturing treatment procedure in a wellbore. Pressure pulse service result depends on the quality of a pressure pulse signal generated during the pumping rate ramp down of the fracturing treatment. However, the sequence of the steps involved in the ramp down may generate suboptimal pressure pulses, such as, e.g. absence of water hammer or highly convoluted signal due to the steps involved in the ramp down. Provided herein are novel ways of controlling pumping rate changes during a ramp down procedure to optimize the pressure pulse signal and address at least these issues.

In some implementations, a machine learning model may be utilized to characterize properties of a subsurface reservoir and the wellbore conditions, to determine/predict an ideal rate change schedule/sequence needed to generate a desired water hammer pressure signal during ramp down. The machine learning model may be trained to calculate wave speed in a wellbore, and then determine a desired rate change based on at least the wave speed, known geometry of the wellbore such as measured depth, casing design, and time of wave traversal. Previous attempts to determine an optimal pressure pulse have included using autocorrelation (visualized by autocorellogram plot) of collected data to analyze a “noisy” signal, such as generated by stair-step rate drop down.

Examples disclosed herein may use a machine learning model to generate a desired signal with minimum convolution/distortion of the ideal water hammer pressure signal/signature. Generating the desired signal does not require frequency domain analysis proposed in other publications. Further, previous solutions have required 100-1000 Hz data, while implementations disclosed herein are based on field applications where pressure is recorded at about 10 Hz data resolution. Examples disclosed herein may help with scaling a pressure service product, delivering a stage efficiency metric with a high success rate.

In one embodiment, a method for determining an optimal rate change schedule may include obtaining geometrical data and fluid properties, which may include pressure pulse data, from a wellbore; calculating wave speed based on the geometrical data and fluid properties; and determining, a rate change schedule for use during a ramp down procedure based on the calculated wave speed. The method may include training a machine learning model, wherein determining the rate change schedule may be performed using the machine learning model. In some implementations, the machine learning model may include computer code and/or a neural network, and be implemented on a non-transitory computer readable medium, circuitry, and/or any other logic components configured to perform the operations described herein.

### Example Systems

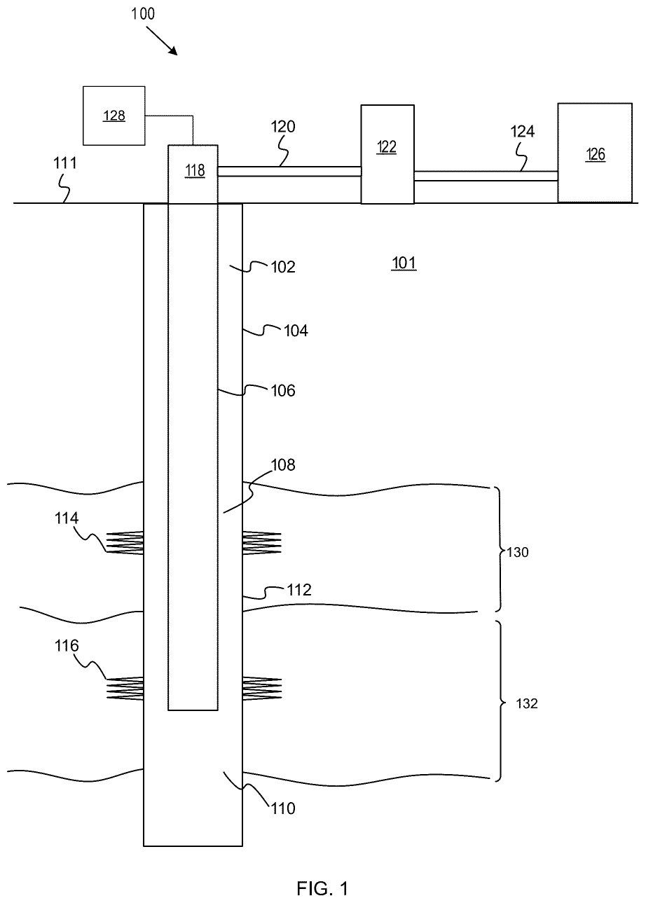

FIG. 1 is a diagrammatic illustration of an example well system, according to some implementations. In particular, a well system 100 of FIG. 1 includes a wellbore 102 in a subsurface formation 101. The wellbore 102 includes casing 104 and number of perforations 114, 116 being made in the casing 104. Each set of perforations 114, 116 is located in a respective reservoir 130, 132 to connect the well with the formation 101 and allow reservoir fluids (i.e., oil, water, and gas) from the respective reservoirs 130, 132 to flow into the wellbore 102 and into the tubular string 106 (the production tubing). Instead of perforations, there could be sliding sleeves having perforations/openings in an outer diameter thereof placed within the wellbore 102.

A flowline 120 coupled to the wellhead 118 of wellbore 102 may allow the fluid produced from the wellbore to flow up the tubular string 106, and also enable a pump 122 to pump fluid into the wellbore 102. The pump 122 may pump a fluid or slurry into the wellbore 102 to fracture the rock, and a proppant in the slurry, such as sand, may fill and prop open the perforations 114, 116 to enable production fluid to enter the flowline 124. The fluid produced from wellbore 102 may then flow to a tank battery, via flowline 124, that may include components such as storage tank 126, to store the different phases of fluid in respective tanks.

Some implementation of methods according to this disclosure may include a hydraulic fracturing and data acquisition instrument system, including sensors (which may include pressure transducers and hydrophone), a pressure source or pulsed pressure source 128 to generate waves in the wellbore 102, and a signal processing apparatus, which may be coupled with or comprise a processor. In some examples pressure or acoustic data may be obtained from fiber-optic measurements. In some examples, a propagating water hammer may be generated either by a change in rate of pumping, or a tube wave that may be generated by the pressure source 128.

### Example Implementations

Disclosed herein are examples of determining an optimal rate change when a ramp down stage is needed in the fracturing process. Although wellbore 102 is provided as an example wellbore, the examples disclosed herein may be used in conjunction with various configurations of vertical or deviated wellbores.

In a normal fracturing treatment, the pumping rate may be brought up to a desired or design max/highest flow rate. For a shut down, or ramp down stage, the pumping rate may be dropped typically in multiple steps, such as 2 to 3 steps, to bring the pressure rate from the highest rate to zero. Dropping rate in ramp down can generate a pressure pulse (may also be referred to as water hammer or tube wave). The pressure pulse may be used to infer properties in and beyond the wellbore. When generating an excitation (pressure pulse), the response signal from the system provides an imprint of the wellbore and beyond wellbore, which can be used for wellbore analysis. The wellbore design is known so getting a good response signal can model effects of the wellbore from the response, such as efficiency of the wellbore stages, and treatments, etc. The efficiency may include measure of ratio of number of perforations taking fluid to the number of perforation holes created, or measure fluid distribution across the clusters such as uniformity index, or simply change of perforation resistance from the design value. Therefore, analyzing the pressure pulse response is very important. A good pressure signal is desirable, so rate changes may be executed in a systematic way to get a better pressure signal to conduct higher quality analysis and extract more information from the signal.

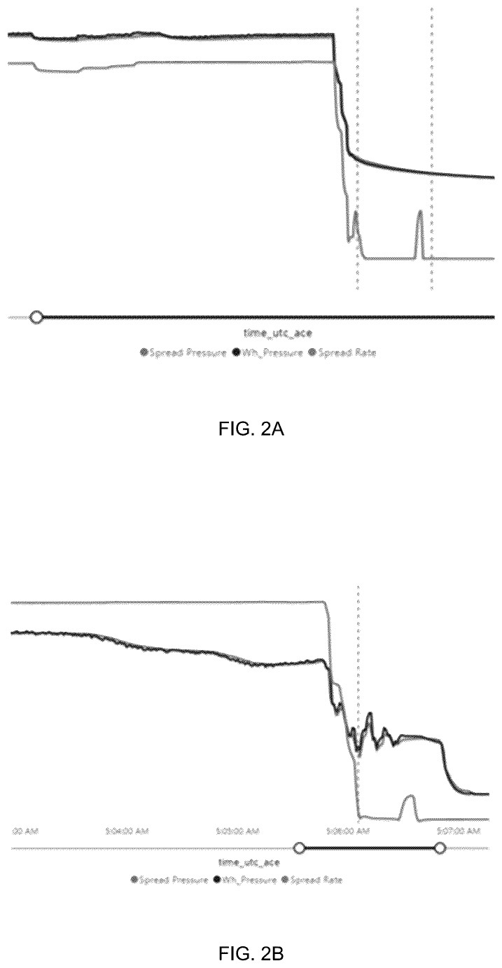

The rate change (rate increase or rate drop) may generally produce a water hammer signal that can be utilized to estimate treatment efficiency. However, if the sequence of steps in the rate changes are not controlled, there may be suboptimal scenarios such as, e.g., lack of water hammer signal or highly convoluted signal due to the steps involved. FIGS. 2A and 2B illustrate examples. FIG. 2A illustrates when the result is no water hammer signal and as such the data. The pressure signal shown in FIG. 2A cannot be analyzed to get any useful information or analytics. If the rate drop steps are not timed correctly, the signal gets overlapped and results in convoluted signal, which is illustrated in FIG. 2B.

A good water hammer/pressure pulse signal provides a high-quality signal. Two different approaches are proposed herein to determine a rate change plan to achieve a good signal. In a first approach, where there are 3 or more steps are utilized, the timing and the magnitude of the rate changes are adjusted such that the resulting water hammer pressure oscillations are cancelled out, so that a clean signal can be obtained prior to the last drop.

When the first pumping rate change (rate drop in this example) is performed the pressure drops and produces a first signal traveling from the surface to the wellbore and reflecting back to the surface. In order to determine the time of a next (second) change, the pressure signal may be observed until the measured pressure raises (or is expected) to peak and then perform the next rate change, or the wave speed from the earlier operation on the well may be estimated, or use an analytical model and perform the rate drop for expected time to peak. Similarly, a rate increase may be used in a counter phase manner as a counter pressure signal source for a previous rate drop at expected minimum of pressure signal from the previous drop. A counter signal produced in the second step cancels out the previous rate drop signal, then a final drop can be made in a third or next step to generate a good signal. At the last drop, if the signal has any remnant of previous actions that may be deemed too noisy, i.e., a remnant signal with amplitude comparable to amplitudes being generated by the chosen rate drops, then the rate is held at a steady state until the noises decay below an acceptable range. The acceptable range will be signal amplitudes significantly smaller than those generated by the rate drops being executed, thereby ensuring that remnant signal will not interfere significantly with signal being generated. Once the pressure signal is steady, a sharp or immediate rate drop, that is, a drop that occurs in a small fraction of one acoustic transit time, is performed to obtain a clear signal. A sharp or immediate drop may when the rate of change of pumping rate, is, for example, if over the past 1 second, the pumping rate is dropped for more than 10 barrels per stroke (bbl) per min, then the rate drop may be considered sharp.

In some examples, noisy may be defined as whether the variance (or standard deviation) of the measured pressure signal is greater than a threshold. For example, if the standard deviation of measured pressure over the last 100 data samples is above 20 psi, then then it is considered as noisy. Noisy may be further defined as the variance or standard deviation of the residual of a model. For example, if the last 100 data samples of pressure are used to fit a linear model, and the standard deviation of model residuals is above 20 psi, then it considered as noisy.

Wave speed may be calculated using the following formula:

$$\frac{1}{{a}^{2}} = \frac{d ρ}{dP} + \frac{ρ}{A} \frac{dA}{dP} \qquad ( 1 )$$

Wave speed in the wellbore may be calculated using the following formula:

$${a}^{2} = \frac{1}{\frac{ρ}{{K}_{f}} + ( 1 - {v}^{2} ) \frac{ρ D}{Et}} \qquad ( 2 )$$

wherein α=wave speed; p=density; P=pressure; K_{f}=Coefficient of stiffness; V=Poisson's ratio; A=area; D=diameter; and E=Young's modulus. With wave speed and known measured depth the time of wave traversal can be computed as (2 L/a), where L is the depth of the current treatment location.

The rate drop magnitudes in success steps can be kept constant to cancel the pressure waves or can be computed using theoretical models for example by Joukoswky relation:

$$Δ p = ρ \cdot a \cdot Δ v \qquad ( 3 )$$

Where p is pressure, ρ=wellbore fluid density, α=wave speed, and v=fluid speed, Δ represents the change in a quantity.

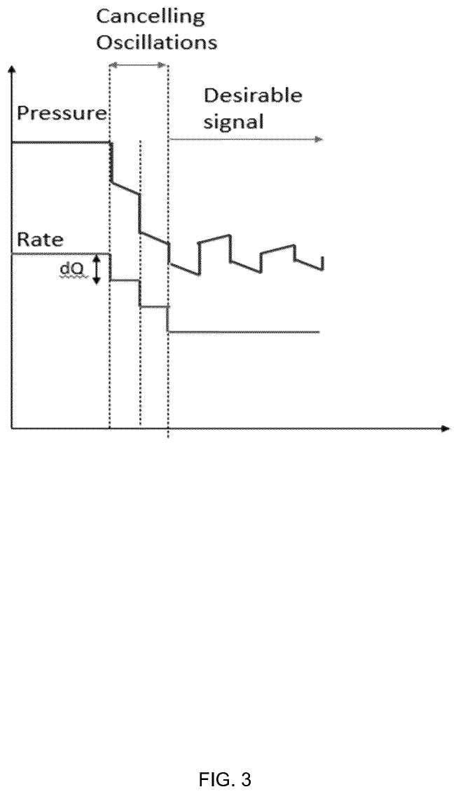

FIG. 3 illustrates a calculated rate change in a discrete manner in 3 steps. FIG. 3 provides a more desirable signal than shown in FIG. 2A-2B, which may then be used for wellbore analysis. If the rate change may be calculated in steps in a discrete manner, the rate change can also be calculated in a continuous manner using limits as dQ (pressure rate drop) goes to zero.

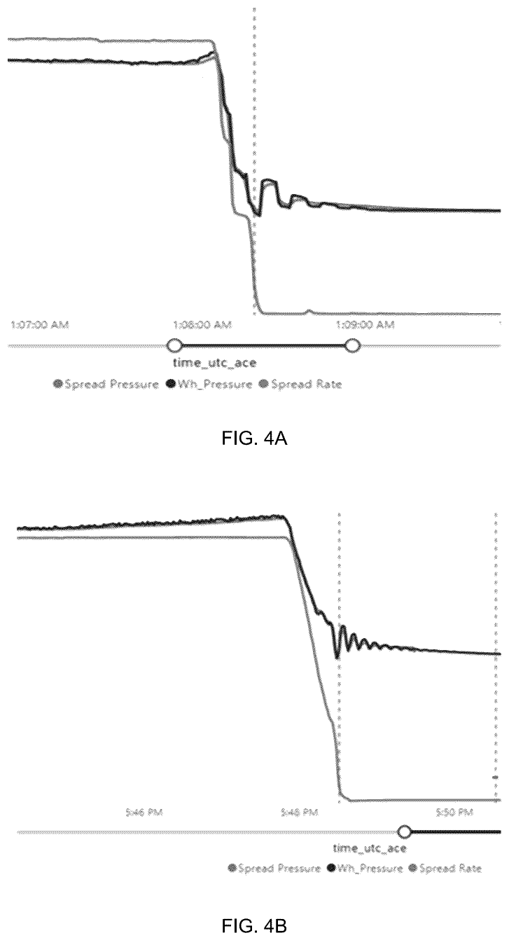

FIGS. 4A and 4B illustrate the result of dropping the rate according to a second approach. FIG. 4A illustrates an example where the rate change (drop in this example) was determined in a continuous linear manner. However, a more desirable signal may still be generated if the rate changes may be done using a continuous variant approach, an infinitely small number of steps), as illustrated in FIG. 4B. For the cases where the pumping rate can be gradually decreased, such as implementations using electric pumps, the rate change is brought down from full rate (such as e.g. 100 bpm) to the last drop, gradually such that pressure follows exponential decay behavior. When the last rate drop value, (such e.g. 20 bpm) is reached, or other determined value as the pressure approaches zero, a sharp ramp down is performed to obtain the pressure pulse signal. This in fact represents a continuous variant of the approach 1 (i.e infinitely small number of steps).

Once the calculations are executed multiple times in the field, multiple rate change schedules may be obtained and the pressure pulse signature may be used to calculate quality scores for rate change schedules executed in the field. The scores indicate the goodness of the generated pressure pulse signal. A quality score may be determined according to how close the generated or measured pressure signal is compared to the ideal or optimal pressure pulse signature (predicted by a physical model or generated from theoretical models). “Optimal” may mean the sum of errors between the measured pressure signal and the modeled pressure signal is minimal. Once all the action and signatures are generated, they may be used as training inputs for a machine learning model. The machine learning model then can predict the ideal rate change sequence to generate higher score signals with known feature inputs.

This data (features) can be input into the machine learning model, along with new wellbore design data to predict optimal sequence of rate change for ramp down to get a good signal. The optimal rate change sequence may also be used with current wellbores to direct or adjust a next treatment in the wellbore to get the desirable signal. The machine learning model may be updated as needed based on new data inputs and design information.

Implementations disclosed herein provide an automated procedure to construct a desired water hammer signal (may also be referred to as tube wave or pressure pulse). In addition, the rate may be temporarily increased if needed to compensate for extremely high pressure drop, which may maximize an interpretability of the water hammer signature and decrease the time required to achieve that pressure signature.

Once enough data is collected for a ramp down process and the pressure pulse signature is of desired quality, a machine learning model can be developed where the model is trained using well geometry, perforation design, a desired shape of pressure pulse signal, and the ramp down sequence as features against the target pressure pulse signal quality. One metric for determining whether the pressure pulse signature is a desired quality may be an L2 norm (“Euclidean norm”)—the difference between observed and predicted pressure from a simulator squared. Another metric that may be used could be how good the signal is compared to a theoretical profile of water hammer pulse data (such as a decaying wave of trapezoidal shape). Once a machine learning model is developed and trained, rate change schedules or ramp down sequence can be obtained from the model for future treatments and wellbore designs.

### Example Operations

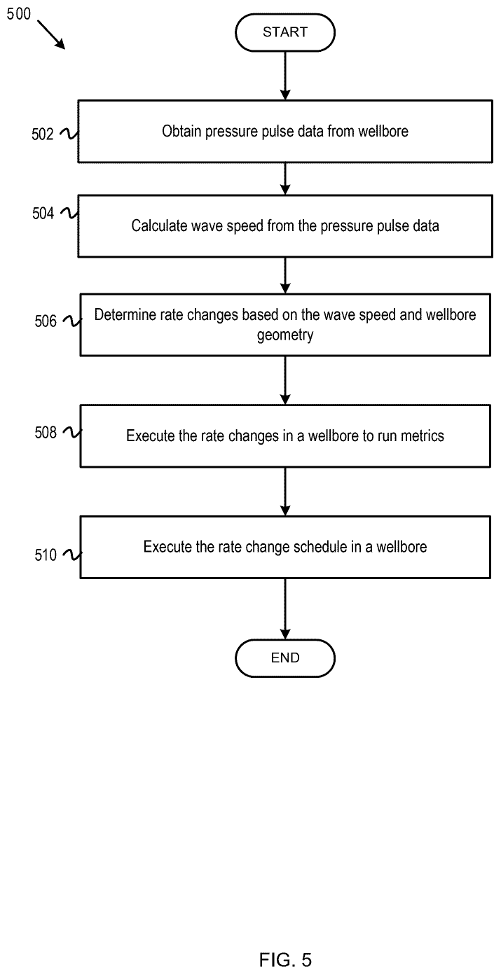

FIG. 5 is a flowchart of example operations for determining a rate change that will provide an ideal or desired signal to be used in wellbore analysis.

Operations of the flowchart 500 begin at block 502. At block 502, geometrical data and fluid properties, which may include pressure pulse data, is obtained from a wellbore, or in some implementations may be modeled based on the wellbore geometry. At a block 504 wave speed is calculated from the pressure pulse data.

At a block 506, rate change signatures (or plans/schedules) may be calculated using the collected pressure pulse data and calculated wave speed. In some examples, the rate change schedules may be calculated according to one of the second approaches illustrated in FIGS. 4A and 4B, where the rate changes are determined in either a continuous linear manner or by using a continuous variant approach.

At a block 508, the calculated rate changes may be executed in a wellbore to run metrics on signals executed in the field.

At a block 508, in some implementations, the calculated rate change schedules may be executed in a wellbore. In some examples, a downhole operation in the wellbore may be modified or updated based on the determined rate change schedule. For example, pumping operations may be designed or modified based on the rate change schedule. In some examples, the rate change schedule may be implemented into the design and operation of a new wellbore. In some implementations, wellbore operations, such as pumping operations for a current wellbore may be adjusted for a next treatment occurring in the wellbore.

At a block 510, the rate change schedule calculated in block 506 may be used to train a machine learning model. The machine learning model may be trained (as described below) to determine rate change schedules for future wellbores or treatments/operations in an existing wellbore based on based on the rate change signatures (or plans/schedules) calculated in block 506 along with wellbore design information.

Some implementations utilize machine learning models to learn from data patterns and make the decisions without knowledge of the explicit relationships. In some implementations, the machine learning model may be configured to learn a function that transforms input data into meaningful predictions or classifications about rate change optimization in a wellbore. The function may be defined by a neural network, including weights, biases, and activation functions for each neuron.

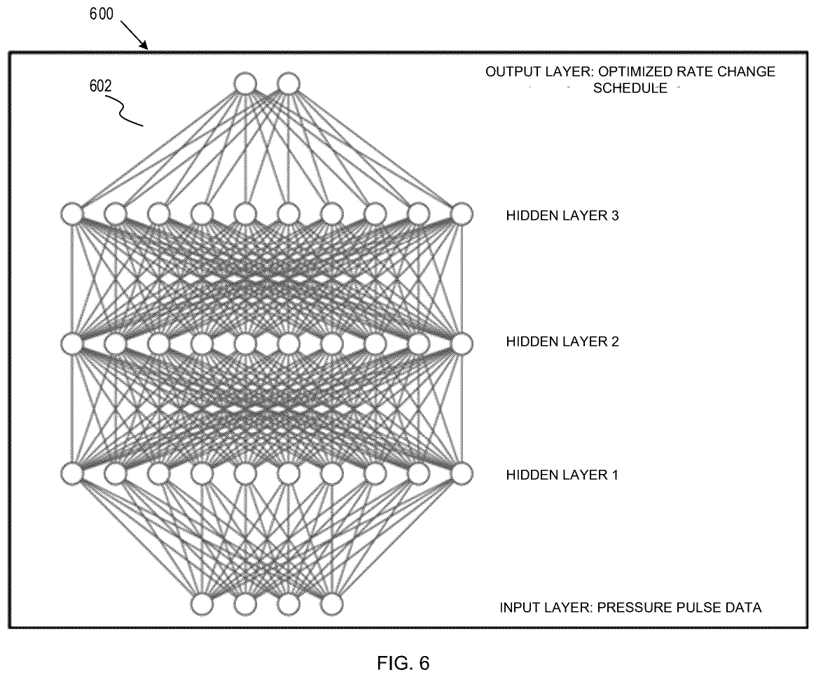

FIG. 6 is diagram illustrating an example neural network 602 that may be used in an example machine learning model 600. The neural network 602 may include an input layer that intakes information (sometimes referred to as features) about the calculated rate changes, pressure responses, hydraulic fracturing treatments, well geometry, and/or any other suitable information about the wellbore, such as, for example, hydraulic fracturing fluid and formation properties. Although the input layer is shown having four neurons, there may be any suitable number of neurons (hence, any suitable number of features). The neural network 602 also may include an output layer that predicts an optimized rate change schedule based on the information that was fed into the input layer.

The neural network 602 may perform training based on wellbore design inputs, fluid properties, pressure pulse signatures and/or any other suitable data about the well. The process for training the machine learning model 600 may find optimal neural network parameters (such as weights, biases, etc.) that match collected pressure pulse signal data along with the calculated rate change signatures/plans.

Operations for training the neural network 602 may include creating or obtaining a training data set and inputting the training data set to the neural network. The training data set may include feature samples and prediction samples. The feature samples may include values derived from past pressure pulses in the well (such as values derived from water hammer data analysis), data about hydraulic fracturing operation in the well, well geometry, and/or any other data described herein or otherwise suitable for training the neural network 602. The feature samples also may include prediction samples. During training, the neural network 602 may receive a group of the feature samples and make a prediction about rate changes or drops based on that group of feature samples. The neural network 602 may validate or invalidate the prediction based on the prediction sample. For example, the neural network 602 may predict a rate change schedule but the prediction sample may indicate that the predicted rate change may not produce a desired signal. In response to this invalid prediction, the training process may modify the neural network 602 (such as by modifying weights, biases, activation functions, etc.).

After the training is complete, the machine learning model 600 may be used to predict rate changes for use during a ramp down stage for new wellbores or may be used to predict rate changes for a next treatment to be performed in an existing wellbore.

### Example Computer

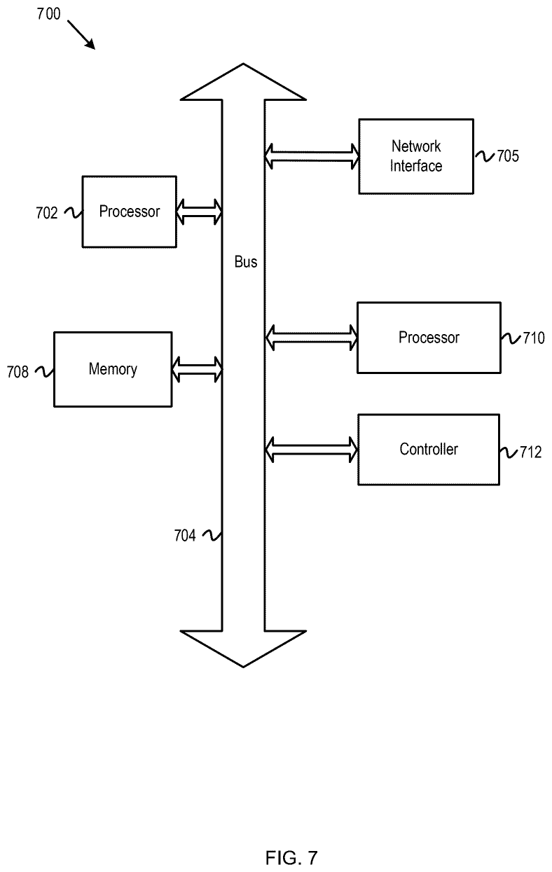

In some implementations, the machine learning model 600 may be integrated into a computer system. FIG. 7 is a block diagram illustrating a computer system 700 that may be utilized with some implementations. Computer system 700 may include one or more processors 702 connected to a system bus 704. The system bus 704 may be connected to memory 708 and a network interface 705. The memory 708 may include any suitable memory random access memory (RAM), non-volatile memory (e.g., magnetic memory device), and/or any device for storing information and instructions executable by the processor(s) 702. The network interface 705 may provide connectivity to any suitable network, such as a wired network, wireless network, satellite network, etc.

The computer system 700 may include additional peripheral devices. For example, the computer system 700 may include multiple external multiple processors. In some implementations, any of the components can be integrated or subdivided.

The computer system 700 also may include a pressure signal processor 710. The pressure signal processor 710 may implement the methods and operations described herein. The pressure signal processor 710 may include a machine learning model 600 (as described herein). The machine learning model 600 may include a neural network 602 or other logic for performing the machine learning operations described herein. In some implementations, the computer system 700 may be included in the well system (such as the well system described with reference to FIG. 1 and may cooperate with other components and/or systems to perform the functionality described herein.

The computer system 700 also may include a pump controller 712 configured to perform operations in response to rate change schedules or predictions.

Any component of the computer system 700 can be implemented as hardware, firmware, and/or machine-readable media including computer-executable instructions for performing the operations described herein. For example, some implementations include one or more non-transitory machine-readable media including computer-executable instructions including program code configured to perform functionality described herein. Machine-readable media includes any mechanism that provides (e.g., stores and/or transmits) information in a form readable by a machine (e.g., a computer system). For example, tangible machine-readable media includes read only memory (ROM), random access memory (RAM), magnetic disk storage media, optical storage media, flash memory machines, etc. Machine-readable media also includes any media suitable for transmitting software over a network.

While the aspects of the disclosure are described with reference to various implementations and exploitations, it will be understood that these aspects are illustrative and that the scope of the claims is not limited to them. In general, predicting rate change schedules via a machine learning model for ramp down or treatment procedures in a wellbore as described herein may be implemented with facilities consistent with any hardware system or hardware systems. Many variations, modifications, additions, and improvements are possible.

Plural instances may be provided for components, operations or structures described herein as a single instance. Finally, boundaries between various components, operations and data stores are somewhat arbitrary, and particular operations are illustrated in the context of specific illustrative configurations. Other allocations of functionality are envisioned and may fall within the scope of the disclosure. In general, structures and functionality presented as separate components in the example configurations may be implemented as a combined structure or component. Similarly, structures and functionality presented as a single component may be implemented as separate components. These and other variations, modifications, additions, and improvements may fall within the scope of the disclosure.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein but are to be accorded the widest scope consistent with this disclosure, the principles and the novel features disclosed herein.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example process in the form of a flow diagram. However, some operations may be omitted and/or other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described should not be understood as requiring such separation in all implementations, and the described program components and systems may generally be integrated together in a single software product or packaged into multiple software products. Additionally, other implementations are within the scope of the following claims. In some cases, the actions recited in the claims may be performed in a different order and still achieve desirable results.

### EXAMPLE IMPLEMENTATIONS

Aspects disclosed herein include:

Aspect A: A method comprising: obtaining pressure pulse data from a wellbore; calculating rate changes for the wellbore; and determining, a rate change schedule for use during a ramp down procedure of a wellbore.

Aspect B: A system comprising: a pressure pump associated with a wellbore; a pressure pulse generator associated with a wellbore; a processor; and a computer-readable medium having instructions stored thereon that are executable by the processor, the instructions including, instructions to calculate rate changes, and instructions to determine a rate change schedule for use during a ramp down procedure of a wellbore.

Aspect C: A non-transitory, computer-readable medium having instructions stored thereon that are executable by a processor, the instructions comprising: instructions to calculate rate changes; and instructions to determine a rate change schedule for use during a ramp down procedure of a wellbore.

Aspects A, B, and C may have one or more of the following additional features in combination:

Feature 1: wherein determining a rate change schedule for use during a ramp down procedure is performed using a machine learning model.

Feature 2: wherein the machine learning model is trained based on multiple wave speed calculations and rate change schedules.

Feature 3: further comprising adjusting pumping operations in a wellbore based on the determined rate change schedule.

Feature 4: wherein adjusting the pumping operation includes changing a pumping rate or adjusting a proppant concentration.

Feature 5: further comprising adjusting a design of a new wellbore based on the predicted rate change schedule and constructing the new wellbore based the adjusted design.

Feature 6: wherein the pressure pulse data includes geometrical data and fluid properties obtained from water hammer pressure pulses arising from hydraulic fracturing operations in the wellbore.

Feature 7: wherein determining, a rate change schedule for use during a ramp down procedure is executed using a machine learning model.

Feature 8: wherein the machine learning model is trained to calculate wave speed.

Feature 9: wherein the rate change schedules are calculated using a continuous variant approach wherein a pumping rate is dropped linearly with respect to time until a desired water hammer pressure signal is reached, whereafter the pumping rate is dropped immediately.

Feature 10: further comprising performing an operation in the wellbore based on the determined rate change schedule.

Feature 11: wherein the wellbore operation includes adjusting pumping operations in the wellbore.

Feature 12: wherein the instructions to determine the rate change are executed using a machine learning model.

Feature 13: further comprising instructions to adjust pumping operations in the wellbore based on the determined rate change schedule.

Use of the phrase “at least one of” preceding a list with the conjunction “and” should not be treated as an exclusive list and should not be construed as a list of categories with one item from each category, unless specifically stated otherwise. A clause that recites “at least one of A, B, and C” can be infringed with only one of the listed items, multiple of the listed items, and one or more of the items in the list and another item not listed.

As used herein, the term “or” is inclusive unless otherwise explicitly noted. Thus, the phrase “at least one of A, B, or C” is satisfied by any element from the set {A, B, C} or any combination thereof, including multiples of any element.

1. A method comprising:
obtaining geometrical data and fluid properties from a wellbore;
calculating wave speed for the wellbore from the geometrical data and fluid properties; and
determining a rate change schedule for use during a ramp down procedure based on the wave speed.

2. The method according to claim 1, wherein determining the rate change schedule for use during a ramp down procedure is performed using a machine learning model.

3. The method according to claim 2, wherein the machine learning model is trained to calculate the wave speed.

4. The method according to claim 1, wherein the rate change schedule is calculated using a continuous variant approach wherein a pumping rate is dropped linearly with respect to time until a desired water hammer pressure signal is, whereafter the pumping rate is dropped immediately.

5. The method according to claim 1, further comprising performing an operation in the wellbore based on the determined rate change schedule.

6. The method according to claim 5, wherein performing an operation in the wellbore includes adjusting pumping operations in the wellbore.

7. The method according to claim 1, wherein the geometrical data and fluid properties include pressure pulse data.

8. The method according to claim 7, wherein the pressure pulse data includes water hammer pressure pulses arising from hydraulic fracturing operations in the wellbore.

9. A system comprising:
a device configured to generate a pressure pulse within a wellbore;
a processor; and
a computer-readable medium having instructions stored thereon that are executable by the processor, the instructions including,
instructions to obtain pressure pulse data from the wellbore;
instructions to calculate wave speed based on the pressure pulse data; and
instructions to determine a rate change schedule for use during a ramp down procedure based on the calculated wave speed.

10. The system according to claim 9, wherein the instructions to determine the rate change schedule are executed using a machine learning model.

11. The system according to claim 10, wherein the machine learning model is trained to calculate wave speed.

12. The system according to claim 9, wherein the rate change schedule is calculated using a continuous variant approach wherein a pumping rate is dropped linearly with respect to time until a desired water hammer pressure signal is reached, whereafter the pumping rate is dropped immediately.

13. The system according to claim 9, wherein pumping operations in the wellbore are adjusted based on the determined rate change schedule.

14. The system according to claim 9, wherein the pressure pulse data is obtained from water hammer pressure pulses arising from hydraulic fracturing operations in the wellbore.

15. A non-transitory, computer-readable medium having instructions stored thereon that are executable by a processor, the instructions comprising:
instructions to obtain pressure pulse data from a wellbore;
instructions to calculate wave speed based on the pressure pulse data; and
instructions to determine a rate change schedule for use during a ramp down procedure based on the wave speed.

16. The non-transitory, computer-readable medium according to claim 15, wherein the instructions to determine the rate change schedule are executed using a machine learning model.

17. The non-transitory, computer-readable medium according to claim 16, wherein the machine learning model is trained to calculate the wave speed.

18. The non-transitory, computer-readable medium according to claim 15, wherein the rate change schedule is calculated using a continuous variant approach wherein a pumping rate is dropped linearly with respect to time until a desired water hammer pressure signal is reached, whereafter the pumping rate is dropped immediately.

19. The non-transitory, computer-readable medium according to claim 15, wherein the pressure pulse data is obtained from water hammer pressure pulses arising from hydraulic fracturing operations in the wellbore.

20. The non-transitory, computer-readable medium according to claim 15, further comprising instructions to adjust pumping operations in the wellbore based on the determined rate change schedule.
